(19) United States
(12) Patent Application Publication
(10) Pub. No.: US 2007/0232070 A1
(43) Pub. Date: Oct. 4, 2007

(54) Method and device for depositing a protective layer during an etching procedure

(76) Inventors: Stephan Wege, Dresden (DE); Axel Henke, Ebersbach (DE)

Correspondence Address: SLATER & MATSIL LLP, 17950 PRESTON ROAD, SUITE 1000, DALLAS, TX, 75252, US

(21) Appl. No.: 11/396,397

(22) Filed: Mar. 31, 2006

(51) Int. Cl. H01L 21/311

(52) U.S. Cl. 438/694

(57) ABSTRACT

A device and method for depositing a protective layer on a material during a plasma etching procedure in the course of fabricating semiconductor components, in particular in the course of fabricating DRAM chips, characterized in that the plasma has at least one precursor which, during the plasma etching procedure, together with a constituent of the plasma at least partially forms a protective layer on a planar region of the material and, characterized by a means for feeding the at least one precursor into the plasma, in which case, by means of the at least one precursor, during the plasma etching procedure, together with a constituent of the plasma, a protective layer can at least partially be deposited on a planar region of the material.

The invention relates to a method according to the preamble of Claim 1 and a device according to the preamble of Claim 13.

In the patterning of materials in the semiconductor industry, etching processes, in particular dry etching processes, are regularly used for patterning substrates. A typical dry etching process is plasma etching, in the course of which a material removal is effected from a plasma. This includes e.g. reactive ion etching (RIE), in which reactive components of the gas atmosphere used also play a part besides ion bombardment. Anisotropic etching, in particular, can be effected by reactive ion etching. Plasma etching also includes ICP (inductively coupled plasma) methods. Combinations of MERIE (MERIE magnetically enhanced RIE), RIE, ECR (electron cyclotron resonance), helicon sources and ICP methods are also possible.

A typical application such as dry etching processes is etching trenches (e.g. deep trench structures required for memory cells in DRAM chips).

The etching of deep trench structures requires a relatively long etching procedure since the etching medium has to act for a long time on the substrate, which under certain circumstances is prepatterned. In this case, however, the etching medium acts not only in a desired manner on the region of the deep trench structure to be etched, but also on other, in particular planar regions which actually should not be affected by the etching. For this reason, it is attempted to improve the selectivity of the etching by process optimization, limits being reached here.

Furthermore, it may be attempted to apply relatively thick mask layers to the regions which are intended actually not to be affected by the etching. As an alternative, it may be attempted to make a mask layer that is present anyway thicker in order to protect the underlying layers during etching.

All these measures increase the complexity of the process.

The present invention is based on the object of providing a method and a device in which, precisely in the case of long etching times, specific parts of the substrate are protected from the etching medium and deep structures can be etched.

The invention relates to a method for depositing a protective layer on a material during a plasma etching procedure in the course of fabricating semiconductor components, in particular in the course of fabricating DRAM chips, characterized in that the plasma has at least one precursor which, during the plasma etching procedure, together with a constituent of the plasma at least partially forms a protective layer on a planar region of the material.

The formation of a planar protective layer increases the etching selectivity without necessitating changes to the layer system. Given the same mask layer thickness, it is possible to increase the maximum possible aspect ratio during the etching procedure.

The invention is explained in more detail below using a plurality of exemplary embodiments with reference to the figures of the drawings, in which:

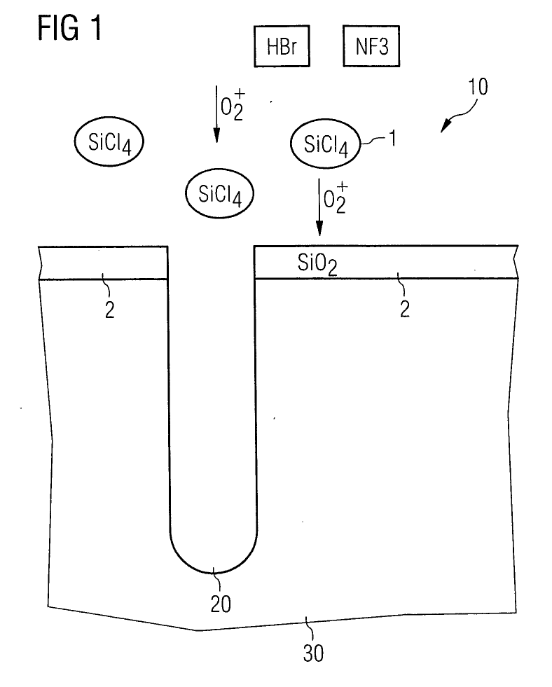

FIG. 1 shows a schematic illustration of an etching of a trench structure in section;

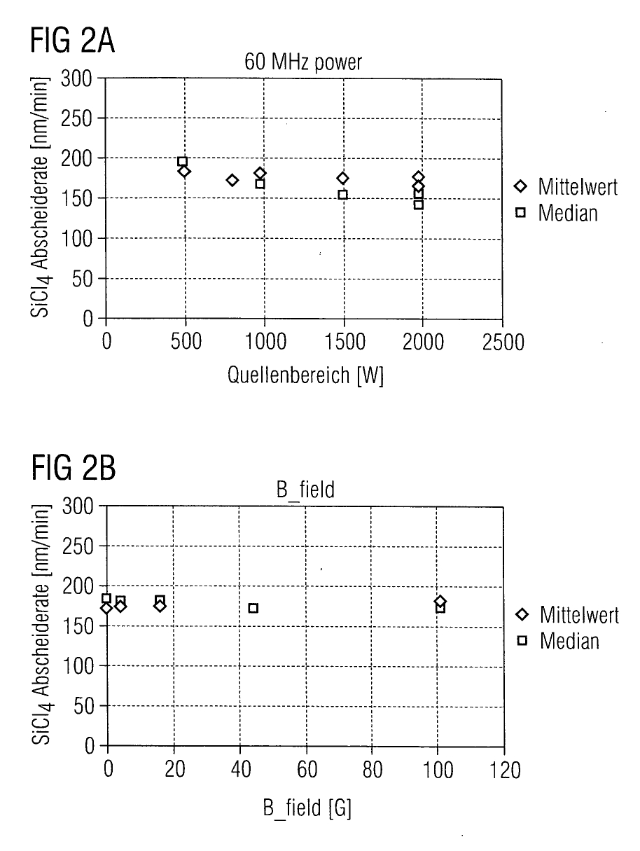

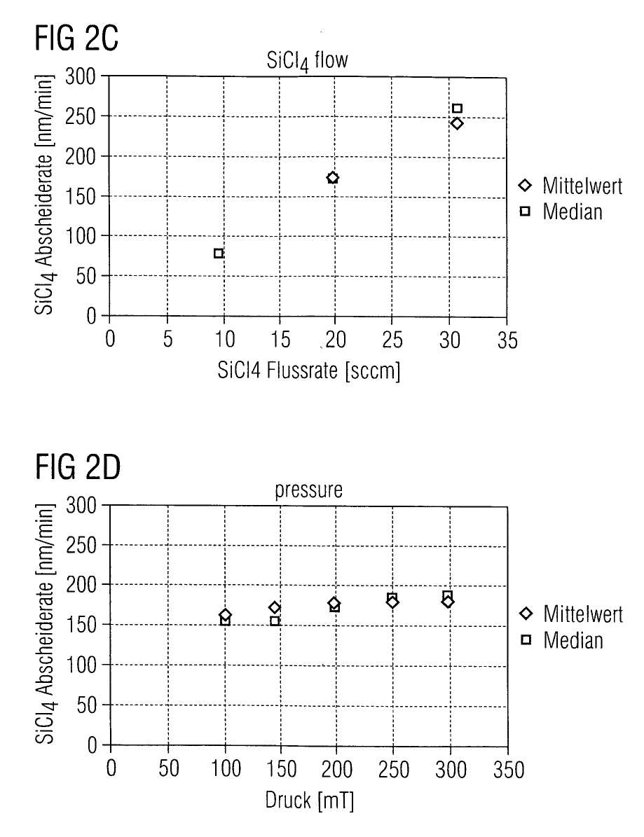

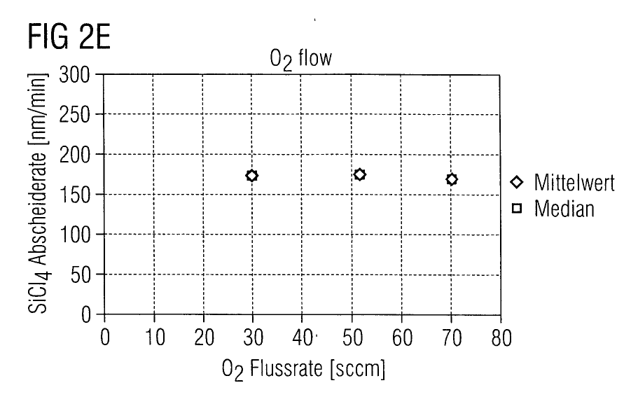

FIGS. 2A-E show measurement results of the deposition rate of the protective layer as a function of source power, magnetic flux density, precursor flow rate (SiCl₄), pressure and oxygen flow rate;

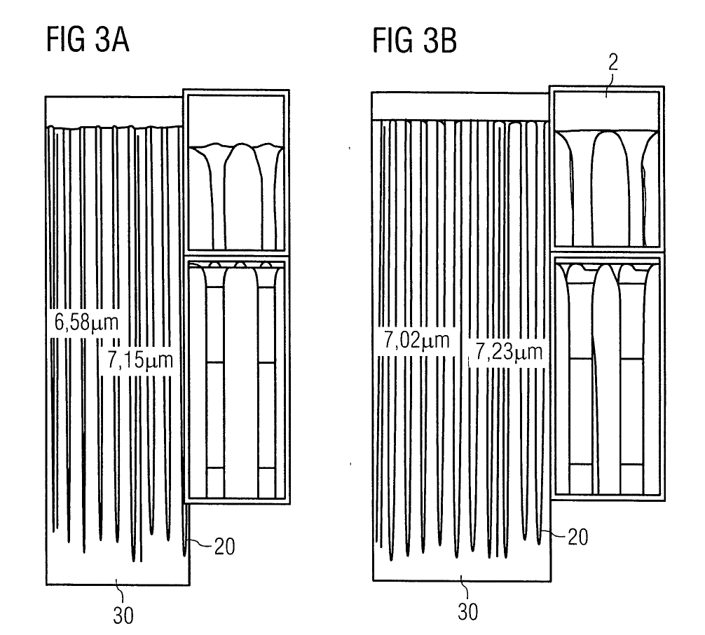

FIGS. 3A, B show an etching result without simultaneous deposition of an etching mask (FIG. 3A center of the substrate, FIG. 3B edge of the substrate).;

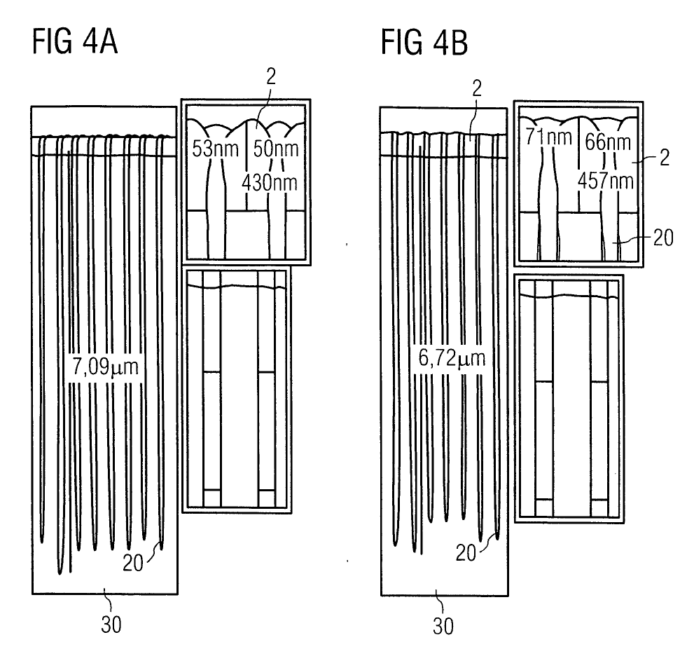

FIGS. 4A, B show an etching result with an embodiment of the present invention (FIG. 4A center of the substrate, FIG. 4B edge of the substrate);

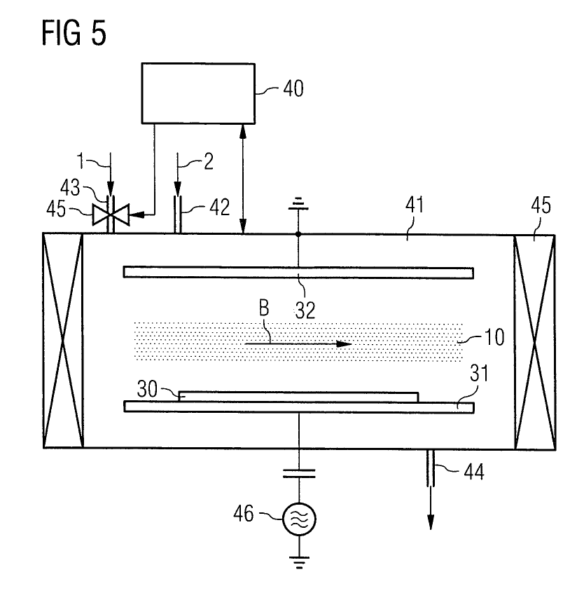

FIG. 5 shows a schematic illustration of an embodiment of a device for carrying out the method according to the invention.

FIG. 1 schematically illustrates a trench structure 20 in a material 30. It shall be assumed here that the material 30 is a silicon wafer for the production of DRAM chips. The silicon wafer has a diameter of 300 mm.

The trench structure 20 here is a deep trench structure of a memory cell having an aspect ratio of approximately 55.

Through a dry etching step by means of a plasma 10, said deep trench structure 20 is introduced into the material 30 by means of HBr, NF₃ as etching medium. Since the etching of the deep trench structure 20 takes a relatively long time, the surfaces of the horizontal layers which lie on the left and on the right of the deep trench structure 20 in FIG. 1 would be removed by the etching procedure.

In accordance with the embodiment of the invention illustrated here, a precursor 1 is added to the plasma 10 in a targeted manner, which precursor reacts together with constituents (O₂) in the plasma 10, with the result that a protective layer 2 forms in a planar manner on the material 30. In this case, planar means that the deposition takes place on the horizontal areas of the material 30 which lie essentially perpendicular to the main direction of the trench structure 20. Material deposited in the region of the deep trench structure is partially removed again in the course of the process.

In the exemplary embodiment illustrated here, the precursor 1 is SiCl₄, which reacts with the oxygen in the plasma 10 to deposit a planar SiO₂ protective layer 2 on the material 30. In this case, it is essential that the deposition of said protective layer 2 takes place during the actual etching procedure, so that although the protective layer 2 can be attacked in the course of etching, the protective layer 2 is always at least partially renewed.

The following process parameters are typical for the exemplary embodiment illustrated here.

| | |
|---|---|
| Etching time | 10 to 2000 seconds |
| Pressure | 12 to 40 Pa |
| Source power (60 MHz) | 500 to 3500 W |
| Source line (2 MHz) | 100 to 5000 W |
| B field (magnetic flux | 0 to 0.015 T |
| density) | |
| Flow rate etching medium | 200 to 500 sccm |
| HBr | |
| Flow rate etchant NF₃ | 20 to 100 sccm |
| Flow rate etchant O₂ | 10 to 100 sccm |
| Flow rate precursor (SiCl₄) | 5 to 200 sccm |

The sccm unit is the customary unit for flow rates in plasma technology and stands for cm³/min under standard conditions.

The values mentioned here apply to a typical reactor volume for processing a 300 mm wafer. For larger or smaller wafer diameters, the flow rates have to be scaled correspondingly.

Depending on the operating characteristics, the protective layer 2 can be deposited continuously during the entire etching procedure or in phases. In this case, in phases means that the deposition procedure is interrupted occasionally during the etching procedure, in particular is interrupted periodically.

FIGS. 2a to 2e in each case illustrate the influence of process parameters on the SiCl₄ deposition rate, that is to say the deposition of the protective layer 2.

It is evident in this case that apart from the SiCl₄ flow rate (see FIG. 2c) into the plasma chamber 41 (see FIG. 5), no other process parameter has a comparable influence on the deposition rate of the protective layer 2. Neither the source power (FIG. 2a), the magnetic field density (FIG. 2b), the pressure (FIG. 2d) or the oxygen flow rate (FIG. 2e) significantly influences the deposition of the protective layer 2.

By virtue of this decoupling, it is possible to control the growth of the planar protective layer 2 in a targeted manner. This applies all the more since the dependence of the deposition rate on the SiCl₄ flow rate is essentially linear. This knowledge therefore enables the targeted control in a plasma etching chamber 41 (see FIG. 5).

FIG. 3 illustrates two sections through a silicon substrate, FIG. 3a showing a sectional view from the center of a wafer and FIG. 3b showing a sectional view from the edge of the wafer. The areas marked with a thick border on the right next to the illustrations each show detail enlargements.

Deep trench structures 20 etched into the silicon substrate 30 are illustrated. The depth of the deep trench structures 20 is between 6.58 μm and 7.23 μm. The aspect ratio is approximately 55 here, that is to say greater than 50. It can be discerned in FIGS. 3a and 3b that no mask layer at all is present any longer. If the etching procedure were continued, it would etch into the material 30 itself, so that the etching depth of the deep trench structure 20 would be limited. The structure would otherwise by destroyed.

FIG. 4, analogously to FIG. 3, illustrates two sections through a silicon substrate (silicon wafer having a diameter of 300 mm), FIG. 4a showing a sectional view from the center of the wafer and FIG. 4b showing a sectional view from the edge of the wafer. In this case, too, a deep trench structure 20 was introduced into a silicon substrate 30, but by means of an embodiment of the method according to the invention as described in connection with FIG. 1. The aspect ratio of the deep trench structures 20 is comparable to that of the structures in FIG. 3.

In contrast to FIG. 3, FIG. 4 reveals, in particular in the detail enlargements marked with a thick border in each case on the right of the illustrations, that in the case of the method according to the invention, a planar protective layer 2 made of SiO₂ was deposited on the surface. In this case, the protective layer 2 has a thickness of between 430 and 460 nm. This protective layer 2, which was built up by the targeted addition of the precursor 1 during the etching procedure, protects the underlying layers, so that a complicated process or material optimization can be dispensed with. On account of the protective layer 2, etching can be effected for longer, so that deeper deep trench structures 20 can be fabricated. An improvement in the selectivity was achieved. It is thus possible to fabricate memory cells having a smaller space requirement in conjunction with a good storage capacity.

The invention has been described here on the basis of an exemplary embodiment in which SiCl₄ was used as precursor 1. In principle, however, other compounds or mixtures of compounds are also suitable as precursor. In the case of silicon-releasing precursors, these would be e.g. the compounds with the following empirical formula: SiAₓH_{y} where
x=0, . . . , 4,
y=0, . . . , 4 and
x+y=4 and
A=Cl or A=F,

in particular also SiH₄, SiF₄ or SiH₂Cl₂.

It is also possible to fabricate protective layers 2 using other materials, e.g. from Al₂O₃, AlN, TiO or TiN. In principle, it is also possible to use different protective layers 2 in combination with one another.

Furthermore, however, it is also possible to use other materials as substrate 30.

Moreover, the invention has been illustrated here on the basis of the fabrication of a deep trench structures 20. However, a protective layer 2 that is built up or obtained in the course of etching can also be used in the fabrication of other structures for semiconductor components. The advantages of the present invention are especially manifested wherever long etching times are required. Thus, the protective layer 2 could also be arranged on the tips of ridges having a high aspect ratio which are etched into a material 30.

FIG. 5 schematically illustrates a plasma chamber 41 as is used e.g. for an MERIE process known per se, so that only the parts essential to the invention are discussed here.

A silicon wafer 30 into which trench structures 20 (not illustrated here) are intended to be etched is arranged in the plasma chamber 41, which is embodied as a parallel plate reactor with two electrodes 31,32. The plasma etching chamber 41 has an inlet 42 for the etching medium 3, e.g. HBr, and an outlet 44 connected to a vacuum pump.

A plasma 10 is generated between the electrodes 31,32 in the plasma chamber 41. A field B that permeates the plasma 10 is applied by means of magnet coils arranged laterally. This is the source of the magnetic enhancement of the RIE process. MERIE processes are distinguished by the possibility of etching high anisotropies at a high etching rate.

A radiofrequency source 46 for 1 to 3 frequencies is coupled to the lower electrode 32 of the plasma etching chamber 41.

The embodiment illustrated in FIG. 5 has a connection 43 for the inflow of a precursor 1, here SiCl₄. The inflow is in this case connected to a control device 40 in a regulatable manner via a valve 45. As illustrated in connection with FIGS. 2a to 2e, the flow rate of the precursor 1 is a very efficient manipulated variable for the deposition rate of the planar protective layer 2. In principle, the control device 40, e.g. in the form of a computer, is connected to the plasma chamber 41 in order, if appropriate, to determine process data which are used for driving the flow rate of the precursor 1.

Even though the method has been described here on the basis of an MERIE process, it is also possible to use ICP (inductively coupled plasma), other RIE, ECR (electron cyclotron resonance), helicon sources and ICP methods.

### LIST OF REFERENCE SYMBOLS

1 Precursor, e.g. silicon-releasing compound
2 Protective layer, e.g. SiO₂, SiO₂-like compound
3 Etching medium
10 Plasma
20 Trench structure, e.g. deep trench structure
30 Material, e.g. silicon wafer
31 Electrode
32 Electrode
40 Control device
41 Plasma chamber
42 Inlet for etchant
43 Inlet for precursor
44 Outlet
45 Valve
46 Magnet coil
47 Radiofrequency source
B Magnetic field

1-14. (canceled)

15. A method of fabricating a semiconductor component, the method comprising:
depositing a protective layer on a material during a plasma etching procedure wherein the plasma has at least one precursor which, during the plasma etching procedure, together with a constituent of the plasma at least partially forms a protective layer on a planar region of the material.

16. The method according to claim 15, wherein the precursor comprises at least one silicon-releasing precursor with a gaseous molecule of the following empirical formula: SiAₓH_{y} where
x=0, . . . , 4,
y=0, . . . , 4 and
x+y=4 and
A=Cl or A=F.

17. The method according to claim 16, wherein the precursor is selected from the group consisting of SiH₄, SiCl₄, SiF₄ and SiH₂Cl₂.

18. The method according to claim 15, wherein the precursor comprises at least one titanium- or aluminum-releasing precursor.

19. The method according to claim 18, wherein the precursor is selected from the group consisting of TiCl₄ and Al₂Cl₆.

20. The method according to claim 15, wherein the etching medium in the plasma has at least one portion of HCl, SF₆, Cl₂, HBr, NF₃ and/or O₂.

21. The method according to claim 15, wherein the plasma reacts together with at least one silicon-containing precursor to form the protective layer with uncharged SiO₂ compounds and/or uncharged SiO₂-like compounds and/or silicon nitride compounds.

22. The method according to claim 15, wherein the plasma reacts together with at least one titanium-containing precursor to form the protective layer with uncharged TiO₂ and/or TiN compounds.

23. The method according to claim 15, wherein the plasma reacts together with at least one aluminum-containing precursor to form a protective layer with an uncharged Al₂O₃ and/or AlN compound.

24. The method according to claim 15, wherein the protective layer is formed continuously during the etching procedure.

25. The method according to claim 15, wherein the protective layer is formed in phases during the etching procedure.

26. The method according to claim 15, wherein a deposition rate of the protective layer is controlled by a flow rate of at least one precursor.

27. The method according to claim 15, wherein the protective layer formed is partially etched.

28. The method according to claim 15, wherein a flow rate of the precursor is between 3 and 50 sccm.

29. The method according to claim 28, wherein the flow rate of the precursor is between 5 and 30 sccm.

30. The method according to claim 29, wherein the precursor comprises SiCl₄.

31. The method according to claim 15, wherein the etching procedure produces a trench structure or a ridge structure in the material with an aspect ratio of 10 to 150.

32. The method according to claim 31, wherein the aspect ratio is between 40 and 80.

33. The method according to claim 15, wherein the etching comprises etching a capacitor trench for a dynamic random access memory chip.

34. A method of making a semiconductor device, the method comprising:
providing a semiconductor wafer;
forming a layer of material over an upper surface of the semiconductor wafer;
forming an opening in the layer to expose a portion of the semiconductor wafer; and
etching the exposed portion of the semiconductor wafer using a plasma etching process that includes at least one precursor that reacts with a constituent to form a protective layer over the layer of material.

35. An apparatus for depositing a protective layer on a material during a plasma etching procedure in the course of fabricating semiconductor components, the apparatus comprising:
a process chamber;
a support for holding a semiconductor component; and
means for feeding at least one precursor into the plasma, wherein, by means of the at least one precursor, during the plasma etching procedure, together with a constituent of the plasma, a protective layer can at least partially be deposited on a planar region of the material.

36. The apparatus according to claim 35, further comprising a control device for the targeted control of the flow rate of the at least one precursor for setting a deposition rate on the material.
